(19) United States
(12) Patent Application Publication
(10) Pub. No.: US 2025/0300641 A1
(43) Pub. Date: Sep. 25, 2025

(54) INPUT BUFFER CIRCUIT

(71) Applicant: TEXAS INSTRUMENTS INCORPORATED, DALLAS, TX (US)

(72) Inventors: Nathan SCHEMM, ROWLETT, TX (US); Sameehan Vivekanand DEODHAR, DALLAS, TX (US)

(21) Appl. No.: 18/776,866

(22) Filed: Jul. 18, 2024

Related U.S. Application Data
(60) Provisional application No. 63/569,245, filed on Mar. 25, 2024.

(51) Int. Cl. H03K 5/01; H03K 17/00

(52) U.S. Cl. CPC H03K 5/01; H03K 17/002

(57) ABSTRACT

An example circuit includes an input divider network, a threshold generator, and a comparator. The input divider network has a first divider input, a second divider input, a first threshold input, a second threshold input, a first divider output, and a second divider output, in which the second divider input is coupled to a signal ground terminal. The threshold generator has first and second threshold outputs and a selection input, in which the first threshold output is coupled to the first threshold input and the second threshold output is coupled to the second threshold input. The comparator has first and second comparator inputs and a comparator output, in which the first comparator input is coupled to first divider output, the second comparator input is coupled to the second divider output, and the comparator output is coupled to the selection input.

### CROSS-REFERENCE TO RELATED APPLICATION

This application claims priority to U.S. Provisional Application No. 63/569,245, filed Mar. 25, 2024, which is incorporated herein by reference in its entirety.

### TECHNICAL FIELD

This description relates an input buffer for a switching output stage.

### BACKGROUND

Power switches are used in a variety of applications to control the supply of electrical power. As an example, a controller can provide an input pulse-width modulated (PWM) signal to a driver circuit, which is configured to provide a drive signal to an output stage (e.g., one or more transistors). The output stage can include one or more transistors. In some circuit configurations, noise can be introduced at the input to the drive circuit, such as from parasitics or other sources, which can distort the input PWM signal. Such distortion can lead to corruption of the drive signal.

### SUMMARY

One described example relates to a circuit that includes an input divider network, a threshold generator, and a comparator. The input divider network has a first divider input, a second divider input, a first threshold input, a second threshold input, a first divider output, and a second divider output, in which the second divider input is coupled to a signal ground terminal. The threshold generator has first and second threshold outputs and a selection input, in which the first threshold output is coupled to the first threshold input and the second threshold output is coupled to the second threshold input. The comparator has first and second comparator inputs and a comparator output, in which the first comparator input is coupled to first divider output, the second comparator input is coupled to the second divider output, and the comparator output is coupled to the selection input.

Another example circuit includes an input divider network, a threshold generator, and a comparator. The input divider network is configured to provide a stepped-down differential input signal, based on an input signal, a ground signal, a first threshold voltage, and a second threshold voltage, in which the input signal and the ground signal define a differential input signal. The threshold generator is configured to provide a provide the first threshold voltage and the second threshold voltage, in which the second threshold voltage changes responsive to a comparator output signal and the first threshold voltage is substantially constant. The comparator is configured to provide the comparator output signal based on the stepped-down differential input signal.

Another described example provides a system that includes a controller and a driver circuit. The controller has a signal output terminal and a signal ground terminal. The driver circuit includes an input buffer circuit and an amplifier. The driver circuit has a first input signal terminal, a second input signal terminal, a driver ground terminal, and a driver output terminal. The input buffer circuit includes an input divider network, a threshold generator, and a comparator. The input divider network has first and second differential inputs, first and second threshold inputs, and first and second differential outputs, in which the first differential input is coupled to the signal output terminal and the second differential input is coupled to the signal ground terminal. The threshold generator has first and second threshold outputs and a selection input, in which the first threshold output is coupled to the first threshold input, and the second threshold output is coupled to the second threshold input. The comparator has first and second comparator inputs and a comparator output, in which the first comparator input is coupled to the first differential output, the second comparator input is coupled to the second differential output, and the comparator output is coupled to the selection input. The amplifier circuit has an amplifier input and an amplifier output, in which the amplifier input is coupled to the comparator output and the amplifier output is coupled to the driver output terminal.

### BRIEF DESCRIPTION OF THE DRAWINGS

FIG. 1 is a schematic block diagram of an example buffer circuit configured to provide a buffered input signal.

FIG. 2 is a circuit diagram of an example input stage circuit.

FIG. 3 is a signal diagram showing examples of some signals in the circuit of FIG. 2.

FIG. 4 is a signal diagram showing examples of simulated signals for the circuit of FIG. 2 during a transient condition at a signal ground terminal.

FIG. 5 is another signal diagram showing examples of simulated signals for the input divider network in the circuit of FIG. 2.

FIG. 6 is another signal diagram showing examples of simulated signals for the input divider network in the circuit of FIG. 2.

FIG. 7 is a schematic block diagram of an example power converter circuit having a driver circuit that includes the buffer circuit of FIG. 1 or 2.

### DETAILED DESCRIPTION

This description relates to an input stage for buffering an input signal and to circuitry that includes the input stage. The input stage provides a wideband input network configured to buffer the input signal with a fast response time enabling fast input propagation. As a result, a driver or other circuitry implementing the input stage can exhibit reduced signal distortion compared to many existing solutions.

As an example, an input stage includes an input divider network configured to provide a stepped-down differential input signal based on a differential input signal and first and second thresholds. For example, the differential input signal includes a pulsed signal (e.g., a pulse-width modulated (PWM) signal) at one differential input and a ground signal at another differential input. A threshold generator is configured to provide the first and second thresholds (e.g., threshold voltages). The first threshold can change responsive to a comparator output signal and the second threshold can be fixed. A comparator is configured to provide the comparator output signal based on the stepped-down differential input signal provided by the input divider network.

In an example, the input divider network includes a resistor divider and a capacitor divider. The resistor divider is configured to step down the differential input signal to provide the stepped-down version thereof and the capacitor divider is configured to provide AC coupling to propagate the stepped-down version of the input signal to the comparator inputs. In an example, the input divider network is implemented on-chip as part of the input stage and configured as an overcompensated resistor-capacitor (RC) network to enable the input stage to propagate the stepped-down version of the input signal to the comparator inputs faster than many existing approaches. Additionally, the threshold generator can be configured to provide each of the thresholds independently to improve DC accuracy of the thresholds with reduced overhead compared to existing approaches.

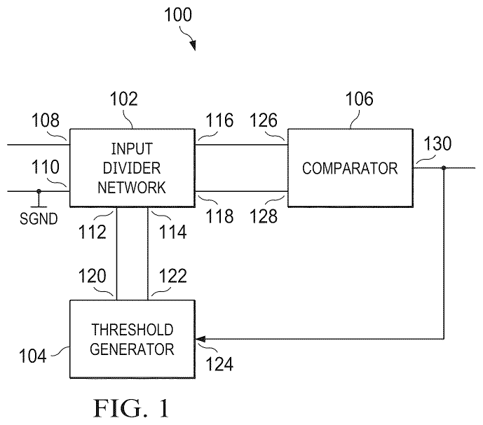

FIG. 1 is a schematic diagram of an example circuit 100. As described herein, in some examples, the circuit 100 constitutes an input stage, such as an input buffer, which is configured to provide a buffered version of an input signal with reduced distortion. The circuit 100 includes an input divider network 102, a threshold generator 104, and a comparator 106. The input divider network 102 has a first and second divider inputs 108 and 110, first and second threshold inputs 112 and 114, and first and second divider outputs 116 and 118. For example, the first and second divider inputs 108 and 110 define a differential input, in which the first divider input receives a time-varying input signal (e.g., a PWM input from a controller) and the second divider input is coupled to a signal ground terminal (SGND). The input divider network 102 thus receives a differential input signal across the first and second divider inputs 108 and 110 and is configured provide differential output signal at the first and second divider outputs 116 and 118 that is a stepped-down (buffered) version of the differential input signal.

In an integrated circuit (IC) that includes the circuit 100, noise can be introduced onto the second divider input 110, such as due to leadframe parasitics. The noise in the second divider input 110 can distort the differential input signal at the first divider input 108 with respect to the SGND at the second divider input 110. Without appropriate correction (e.g., implemented by the input divider network 102) as described herein, the distortion further can corrupt the differential output signal provided at the first and second divider outputs 116 and 118. Accordingly, the input divider network 102 is configured to provide the differential output signal based on the differential input signal (e.g., the time-varying input at 108 with respect to SGND) and threshold voltages received at the respective first and second threshold inputs 112 and 114. For example, the input divider network 102 includes a resistive network and an overcompensated capacitive network.

The threshold generator 104 has first and second threshold outputs 120 and 122 and a selection input 124. The first and second threshold outputs 120 and 122 are coupled to the first and second threshold inputs 112 and 114, respectively. The threshold generator 104 is configured to provide a provide the first and second threshold voltages at the respective first and second threshold inputs 112 and 114. For example, the threshold generator 104 is configured to provide the first threshold voltage at 112 as a substantially constant voltage and provide the second threshold voltage at 114 as a voltage that changes (e.g., between different threshold voltages) responsive to a comparator output signal at the selection input 124. The threshold generator 104 can provide the second threshold voltage at 122 with a first voltage responsive to the comparator output signal at 124 having a first state and a second voltage responsive to the comparator output signal having a second state. The values of the first and second voltages can be configurable parameters that can be set according to application requirements.

The comparator 106 has first and second comparator inputs 126 and 128 and a comparator output 130. The first and second comparator inputs 126 and 128 are coupled to the first and second divider inputs 116 and 118, respectively, and the comparator output 130 is coupled to the selection input 124. The comparator 106 is configured to provide the comparator output signal at the comparator output 130 based on the stepped-down differential input signal received at the first and second comparator inputs 126 and 128. In an example, the comparator 106 is configured to digitize the differential voltage between the respective voltages at the first and second comparator inputs 126 and 128. The comparator output signal thus can be a buffered version of the input signal provided at the first divider input 108, such as can be a pulse or rectangular waveform (e.g., a PWM signal) that changes between on and off states (e.g., between different voltage levels). For example, the comparator output signal thus has a duty cycle, which can be fixed or variable, depending on the input signal received at the first divider input 108. As described herein, the comparator output signal provided at the comparator output 130 can exhibit lower distortion than existing approaches.

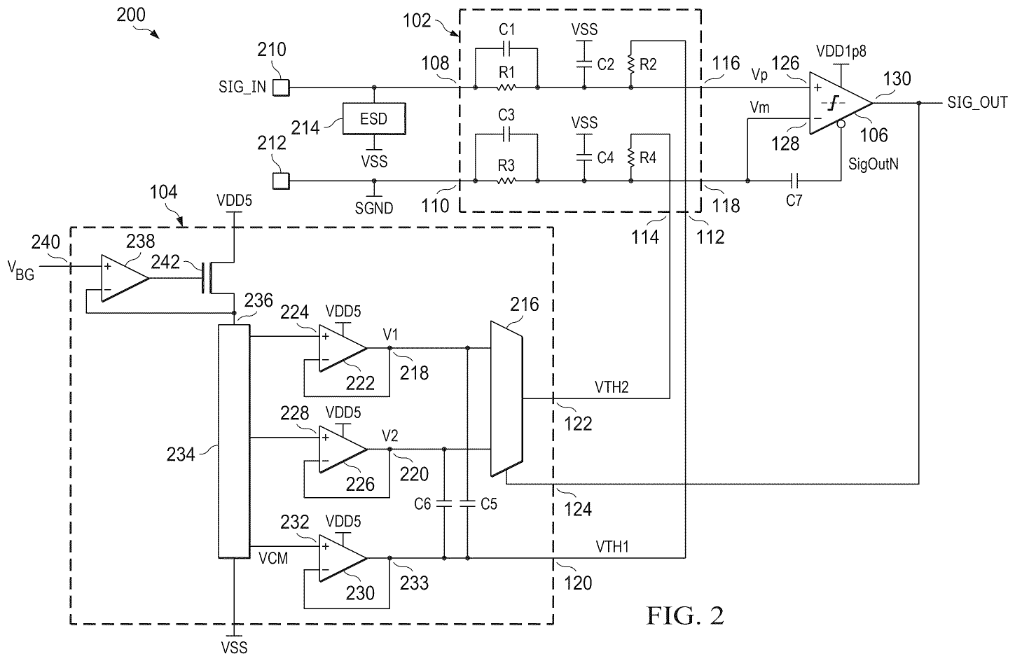

FIG. 2 depicts an example input buffer circuit 200. The input buffer circuit 200 is an example of the circuit 100 of FIG. 1. Accordingly, the description of FIG. 2 can refer to certain aspects of the description of FIG. 1. For example, the circuit 200 includes an input divider network 102, a threshold generator 104, and a comparator 106. The input divider network 102 includes first and second divider inputs coupled to an input terminal 210 and signal ground terminal 212, respectively. The input divider network 102 also includes first and second divider outputs coupled to respective inputs 126 and 128 of the comparator 106. The threshold generator 104 includes first and second threshold outputs 120 and 122 coupled to the respective threshold inputs 112 and 114 of the input divider network 102. In some examples, the circuit 200 can be implemented as part of an IC, in which the input terminal 210 and signal ground terminal 212 can correspond to (or be coupled to) pins of the IC.

In the example of FIG. 2, the input divider network 102 includes resistor and capacitor networks. The resistive network includes a first resistor divider of resistors R1 and R2 and a second resistor divider of resistors R3 and R4. For example, the resistor R1 is coupled between the first divider input 108 and the first divider output 116, which is coupled to first comparator input 126. The resistor R2 is coupled between the first divider output 116 and the first threshold input 112. The resistor R3 is coupled between the second divider input input 110 and the second divider output 118, which is coupled to the second comparator input 128. The resistor R4 is coupled between the second divider output 118 and the second threshold input 114.

The capacitor network includes a first capacitor divider of capacitors C1 and C2 and a second capacitor divider of capacitors C3 and C4. For example, the capacitor C1 is coupled in parallel with R1 between the first divider input 108 and the first divider output 116. The capacitor C2 is coupled between the first divider output 116, which is coupled to the first comparator input 126, and a driver ground terminal, shown as VSS. For example, one or more inherent parasitic components (e.g., a parasitic inductance from the leadframe) of the circuit 200 are coupled between the driver ground terminal VSS and the signal ground terminal SGND. The capacitor coupled C3 is coupled in parallel with R2 between the second divider input 110 and the second divider output 118. The capacitor C4 is coupled between the second divider output 118 and the driver ground terminal VSS.

In the example of FIG. 2, the resistors R1, R2, R3, and R4 are arranged and configured to step down a common mode portion of the differential input signal at divider inputs 108 and 110 and provide a stepped-down version of the differential input signal. The capacitors C1, C2, C3, and C4, which define the capacitor network, are arranged and configured to propagate a compensated, stepped-down differential input signal to the comparator inputs 126 and 128, shown as respective positive and negative (minus) voltages VP and VM. In some examples, the resistor dividers (e.g., R1, R2, R3, and R4) are implemented on-chip with the capacitors C1, C2, C3, and C4 and the comparator 106 to enable a well-matched capacitor divider network as well as reduces the overall area for the circuit 200 compared to approaches that include off-chip resistors. Because the input divider network 102 includes an overcompensated RC network to provide the differential input signal with reduced propagation delay, the circuit 200 can also include an electrostatic discharge (ESD) circuit 214 coupled between the divider input 108 and the driver ground terminal VSS. The ESD circuit 214 is configured to protect the input terminal 210 from transients (e.g., voltage and/or current spikes). For example, the ESD circuit 214 can be implemented as transient voltage suppressor diodes, Zener diodes, or MOSFET-based circuits to name a few.

The threshold generator 104 includes a multiplexer 216 having first and second multiplexer inputs 218 and 220, the selection input 124, and a multiplexer output. The multiplexer output constitutes (or is coupled to) the second threshold output 122, which is coupled to the second threshold input 114 of the input divider network 102. The threshold generator 104 also includes a first buffer 222 having a first buffer input 224 and a first buffer output, in which the first buffer output is coupled to the first multiplexer input 218. The first buffer 222 is configured to provide a first reference voltage V1 at the first multiplexer input 218. A second buffer 226 has a second buffer input 228 and a second buffer output, in which the second buffer output is coupled to the second multiplexer input 220. The second buffer 226 is configured to provide a second reference voltage V2 at the second multiplexer input 220, The threshold generator 104 also includes a third buffer 230 having a third buffer input 232 and a third buffer output 233, in which the third buffer output constitutes (or is coupled to) the first threshold output 120 and is coupled to the first threshold input 112. The third buffer 230 is configured to provide a third reference voltage, which can be a common mode voltage VCM for the differential threshold that the threshold generator 104 provides at the first and second threshold outputs 120 and 122.

As shown in the example of FIG. 2, each of the buffer inputs 224, 228 and 232 is coupled to a respective voltage terminal for receiving a respective voltage provided by a voltage supply 234. The voltage supply 234 has a voltage input 236, and respective ladder outputs, in which each of the ladder outputs is coupled to a respective one of the buffer inputs 224, 228 and 232. As an example, the voltage supply 234 is implemented as a resistor ladder circuit configured to provide respective voltages to the buffer inputs 224, 228 and 232 at (or proportional to) a desired threshold voltage by dividing down the voltage input at 236 according to where each ladder output taps the resistor ladder. An input supply circuit can be configured to provide a fixed input voltage (e.g., 1.2 V or another voltage) at the voltage input 236. For example, a voltage buffer 238 has a first voltage input 240 adapted to be coupled to a terminal that receives a bandgap voltage VBG. An output of the voltage buffer is coupled to a control input (e.g., gate) of a transistor 242, which is coupled between a voltage supply terminal (at VDDS) and the voltage input 236 of the voltage supply 234. The voltage buffer 238 and transistor 242 can be configured to supply a voltage at the voltage input 236 that is equal or proportional to the bandgap voltage VBG. As a result, the voltages at each of the buffer inputs 224, 228 and 232 can be derived from the voltage received at the voltage input 236.

The threshold generator 104 can also include a capacitor C5 coupled between the first multiplexer input (e.g., output of buffer 222) 218 and the third buffer output 233 and a capacitor C6 coupled between second multiplexer input (e.g., output of buffer 226) 220 and the third buffer output 233. The capacitors C5 and C6 are configured to provide AC coupling between the respective threshold voltages at 122 and 120 to improve uniformity of the threshold voltages provided to the comparator inputs 126 and 128. For example, the AC coupling provided by capacitors C5 and C6 (e.g., where C5=C6) enables AC bounce or other noise introduced on the voltage VCM at the threshold output 120 to affect each of the reference voltages V1 and V2 equally.

The threshold generator 104 is thus configured to provide the first threshold voltage VTH1 at the first threshold output 120 and the second threshold voltage VTH2 at a second threshold output 122. As described herein, the threshold generator 104 is configured to vary the second threshold voltage VTH2 between the first reference voltage V1 and the second reference voltage V2 responsive to the comparator output signal received at the selection input 124.

The threshold generator generates the threshold voltages VTH2 and VTH1 to implement an offset between the voltages VP and VM provided at the respective comparator inputs 126 and 128. As described herein, the threshold generator is configured to change the threshold voltage VTH2 between V1 and V2 responsive to the comparator output signal at 130 (e.g., a PWM signal), which results in two different differential threshold voltages (e.g., VTH2−VTH1) across the respective threshold inputs 114 and 112. The different threshold voltages VTH2−VTH1 further introduce hysteresis for creating respective rising-edge and falling-edge thresholds. By generating the threshold voltages VTH1 and VTH2 in this way, DC accuracy can be improved without requiring additional circuitry like common mode comparators.

As a further example, assuming a resistor divider ratio of 24:1 and a capacitor divider ratio of 1:16, the voltage VP and VM at the inputs 126 and 128 can be determined as follows:

$$\begin{matrix}V P - V M = 1 / 25 * ( SIG\_IN - SGND ) , and \\ SIG\_IN - SGND = 25 * ( V P - V M ) ;\end{matrix}$$

where: SIG_IN is the input voltage at 210, and
SGND is the input voltage at 212 (e.g., corresponding to SGND with noise due to parasitics associated with the leadframe).

From the above, it can be shown that:

$$V P = V TH * 24 / 25 , and V M = V TH 1 * 24 / 25$$

The following describes how the input voltages VP and VM can vary based on changes in the threshold voltage VTH2, which is provided at the threshold input 114 as either V1 or V2 based on the comparator output signal. In this example, it is assumed that V1>V2>VCM. As an example, for the scenario of a high input threshold (VIH) when VTH2=V1=586 mV, VP and VM become:

$$\begin{matrix}V P = 24 / 25 * 586 mV = 563 mV , and \\ V M = 24 / 25 * 503 mV = 483 mV .\end{matrix}$$

As a result, the comparator threshold (VP−VM)=0.563−0.483=0.08 V.
Scaling up by 25 (e.g., according to the resistor divider, which scaled down the input signals), the high input threshold becomes:

$$V IH = 0 + 0.08 \times 25 = 2 V .$$

For another example, namely, for a low input threshold (VIL) when the second threshold voltage VTH2=V2=546 mV, VP and VM become:

$$\begin{matrix}V P = 24 / 25 * 546 mV = 523 mV , and \\ V M = 24 / 25 * 503 mV = 483 mV\end{matrix}$$

As a result, the comparator threshold (VP−VM)=0.523−0.483=0.04 V.
Scaling up by 25 (e.g., according to the resistor divider, which scaled down the input signals), the low input threshold (VIL) becomes:

$$V IL = 0 + 0.04 \times 25 = 1 V .$$

While the examples described above are for a resistor divider ratio of 24:1 and a capacitor divider ratio of 1:16, other divider ratios can be used in other examples. Also, or as an alternative, other voltages can be provided from the supply for providing the respective threshold voltages VTH1 and VHT2.

As described herein, because the threshold generator 104 is configured to change the second threshold voltage VTH2 with respect to the first threshold voltage VTH1 with changes in the output signal at 130, a hysteresis condition is introduced that affords glitch protection. In the absence of such hysteresis, in some approaches, a bounce in the ground signal VSS could turn the buffer output signal SIGOUT at 130 in the opposite direction from intended by the input signal SIG_IN received at 210 (e.g., from a controller). The hysteresis can be defined as a difference between the low and high input thresholds VIH and VIL, and continuing with the above example, can be expressed as VIH−VIL=2−1=1V.

As a further example, the following describes transient current requirements (e.g., a minimum current) that each of the buffers 222, 226 and 230 would need to handle to enable to provide a constant voltage output. For V1 buffer 222, the transient current requirement can be expressed as:

$$( V\_SGND - V U ) / ( R 3 + R 4 ) = 0 - 586 mV / 560 k = - 1.04 μA ,$$

where:
   V_SGND represents the voltage of SGND at the second divider input 110, and
   R3+R4=560 kΩ.
      Similarly, for the V2 buffer 226, the transient current requirement can be expressed as:

$$( V\_SGND - V D ) / ( R 3 + R 4 ) = 0 - 546 mV / 560 k = - 0.98 μA .$$

And for VCM buffer 230, the transient current requirement can be expressed as:

$$( {V IN}_{max} - V CM ) / ( R 1 + R 2 ) = ( 26 - 0.5 ) V / 560 k = 45.5 μA ,$$

where R1+R2=560 kΩ.

From the above, it is shown that a large quiescent current (I_{q}) can be introduced through the common mode voltage VCM that is provided at 120. Accordingly, to accommodate the large quiescent current and reduce the bounce on VCM from affecting each of the threshold voltages V1 and V2, the capacitors C5 and C6 can be included to provide AC coupling between VCM and each of V1 and V2, as described herein.

The comparator 106 is thus configured to provide a comparator output signal SIG_OUT at 130 based on the input signal SIG_IN (e.g., a PWM signal), the signal ground SGND, and the first and second threshold voltages VTH1 and VTH2. A capacitor C7 can be coupled between an inverted comparator output (SIG_OUTN) and the comparator input 128. The capacitor C7 is configured to provide coupling between the negative input VM at the comparator input 128 and the inverted SIG_OUT signal. The purpose of the capacitor C7 is to enable the voltage VM to rapidly switch between the two thresholds responsive to the multiplexer 216 switching states. Without the capacitor C7, the voltage VM at comparator input 128 would more slowly transition to the new threshold when the multiplexer 216 changes state.

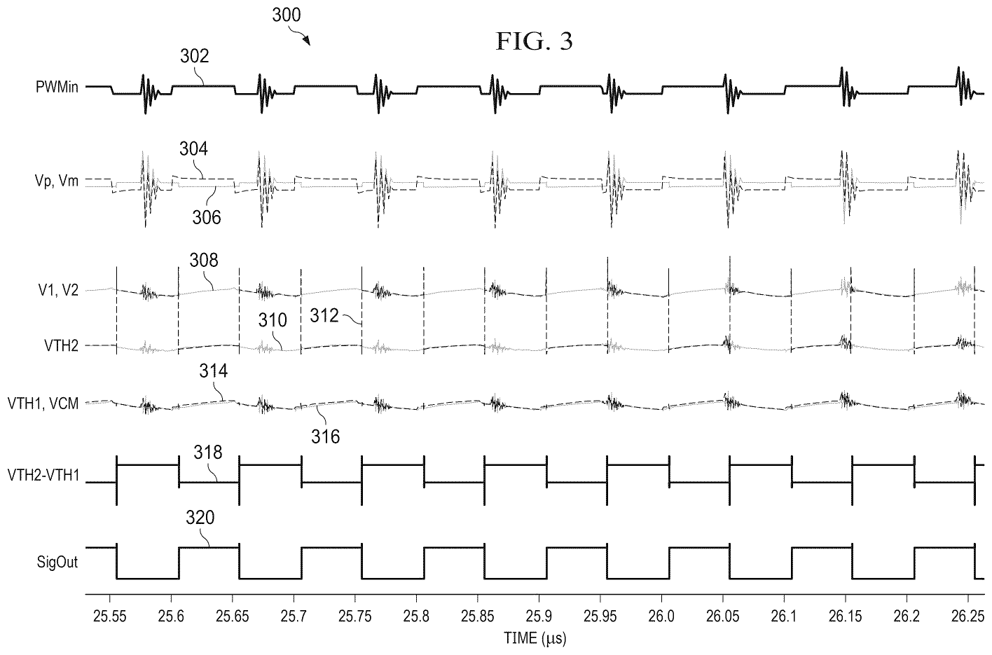

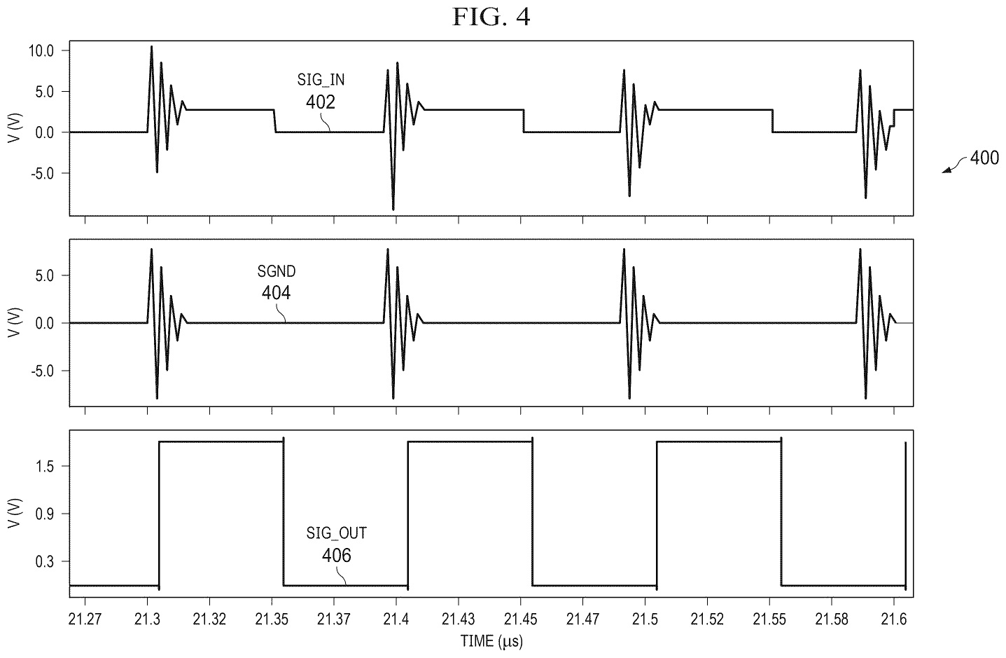

FIG. 3 is a signal diagram 300 showing some signals in the circuit 200 of FIG. 2 for an example simulation. Accordingly, the description of FIG. 4 also refers to FIG. 2. For example, an input PWM signal 302 is provided at the input terminal 210 as the input signal SIG_IN. The input PWM signal 302 includes noise (e.g., due to parasitics) during the off-time. Stepped-down comparator input voltage signals 304 and 306 (e.g., signals VP and VM) are provided at comparator inputs 126 and 128, respectively. The stepped-down comparator input voltage signals 304 and 306 exhibit fast responses times due to the overcompensated capacitor divider in the input divider network 102. Reference voltages V1 and V2 (e.g., at buffer outputs 218 and 220) are shown at 308 and 310. The positive threshold voltage VTH2 is shown at 312, thus changing between the reference voltage signals 308 and 310 to provide hysteresis. The common mode voltage VCM (e.g., at the buffer input 232) is shown at 314, which is used to provide the negative threshold VTH1, shown at 316. The VCM and VTH1 signals exhibits ripple, as shown, which can be coupled onto the V1 and V2 signals 308 and 310 (e.g., through capacitors C5 and C6) to help provide constant threshold voltages. The differential threshold voltage (VTH2−VTH1) is shown at 318, which is provided across the first and second threshold inputs 112 and 114. The resulting output signal SIG_OUT at the comparator output 130 is a PWM output signal 320. Advantageously, PWM output signal 320 does not exhibit any glitches even though the PWM IN has noise.

FIG. 4 is another signal diagram 400 of some signals in the circuit of FIGS. 1 and 2 for an example simulation. Accordingly, the description of FIG. 4 also refers to FIGS. 1 and 2. The signal diagram 400 includes input signals SIG_IN and SGND, shown at 402 and 404, which define a differential input signal across input terminals 210 and 212. The circuit 100, 200 is configured to provide a clean output signal SIG_OUT, shown at 406. In the example signal diagram 400, the SGND signal includes ringing from approximately −8V to about 8V. Despite such ringing, the circuit 100, 200 is configured to provide a 1.8 clean buffer output signal 406 at the comparator output 130 that follows the 3V PWM input.

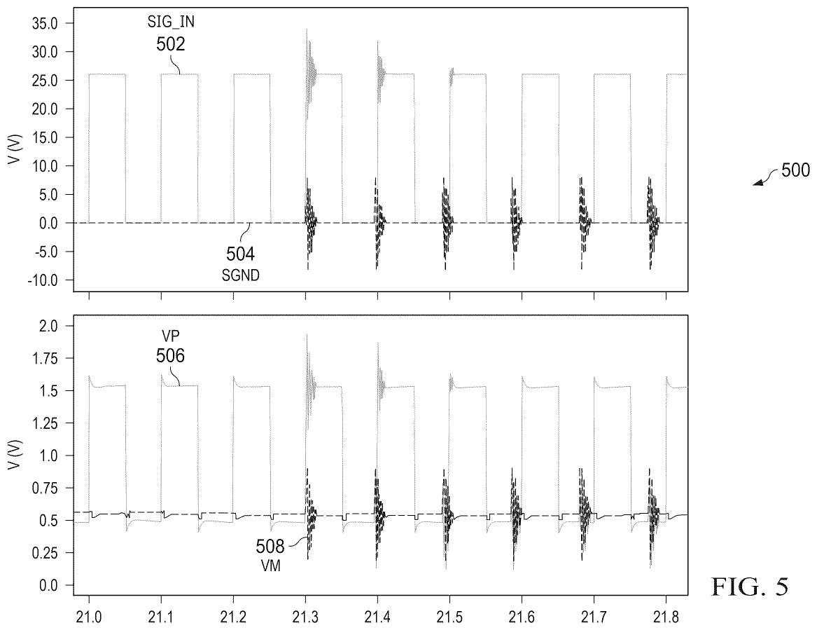

FIG. 5 is a signal diagram 500 for some signals in the circuits of FIGS. 1 and 2 for an example simulation showing operation of the input divider network 102. Accordingly, the description of FIG. 5 also refers to certain aspects of FIGS. 1 and 2. The signal diagram 500 includes the input signals SIG_IN and SGND, shown at 502 and 504, and the comparator input signals VP and VM (e.g., at comparator inputs 126 and 128), shown at 506 and 508, respectively. FIG. 5 thus demonstrates that the input divider network 102, which includes resistor and capacitor networks, can achieve a wideband response to the input signals that is faster than many existing approaches.

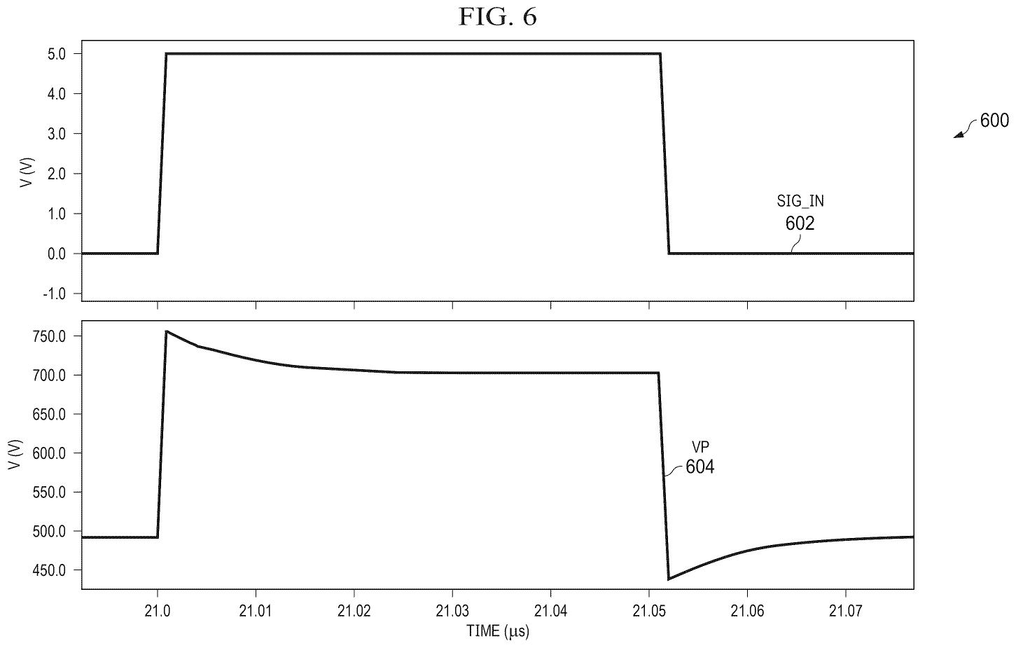

The ability of the overcompensated input divider network 102 to respond quickly is further demonstrated in the signal diagram 600 of FIG. 6. The signal diagram 600 shows a zoomed in view of the input signal SIG_IN 602 and the resulting comparator input signal VP 604 at the comparator input 126. A comparison of the rising edges of the signals 602 and 604 shows little delay between the respective signals, which is due largely to the overcompensated RC network.

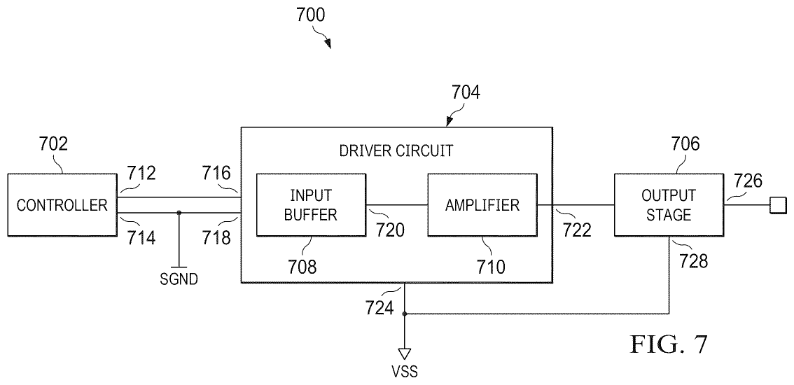

FIG. 7 is a schematic block diagram of an example power converter circuit 700. The power converter circuit 700 includes a controller 702, a diver circuit 704, and an output stage 706. The driver circuit 704 includes an input buffer circuit 708 and an amplifier circuit 710. The input buffer circuit 708 can be implemented by the circuit 100, 200 of FIG. 1 or 2. Accordingly, the description of FIG. 7 can also refer to certain aspects of FIGS. 1 and 2. The controller 702 includes controller outputs 712 and 714 coupled to respective drive inputs 716 and 718. The driver inputs driver inputs 716 and 718 can be (or be coupled to) the first and second divider inputs 108 and 110 of the input divider network 102. With reference to the example of FIG. 2, the respective drive inputs 716 and 718 can be implemented as the input terminals 210 and 212, respectively. The input buffer circuit 708 has an output (e.g., the comparator output 130) 720, which is coupled to an input of the amplifier circuit 710. For example, the input buffer circuit 708 includes an input divider network 102, a threshold generator 104, and a comparator 106, and is configured to provide a buffered version of the input signal (e.g., a PWM signal received from the controller 702) at the buffer output 720, as described herein. The controller 702 can be configured to provide a PWM signal at the controller output 712 and the controller output 714 can be coupled to a signal ground terminal (SGND). The amplifier circuit 710 is configured to provide an amplifier output signal at a driver output 722 (e.g., an output terminal of the driver circuit 704), which is coupled to an input of the output stage 706, responsive to the signal provided at 720. The driver circuit 704 also includes a driver ground terminal 724 coupled to a driver ground (VSS).

The output stage 706 has a drive input coupled to the driver output terminal 722. The output stage 706 also has a switching output 726 and an output ground terminal 728. The output ground terminal 728 is coupled to the driver ground terminal 724, and the output ground terminal can be coupled to the signal ground terminal through a parasitic inductance (e.g., leadframe parasitics of the output stage 706). A load (not shown) can be coupled to the switching output 726. The output stage 706 is configured to provide an output at the switching output 726 responsive to the drive signal provided at 722.

In an example where the output stage 706 includes one or more metal oxide semiconductor field effect transistors (MOSFETs) arranged and configured to supply power (e.g., regulated voltage and/or current) to a load responsive to the amplifier output signal at the driver output 722, the amplifier circuit 710 can be implemented as one or more gate driver circuits. Other types and configurations of circuits can be used to implement the output stage in other examples.

In some examples, the driver circuit 704, including the input buffer circuit 708 and amplifier circuit 710, are implemented on a respective IC (e.g., a chip or die). The controller 702 can be implemented on another IC chip or by discrete components. The output stage 706 can include one or more transistors (e.g., field effect transistors, bipolar junction transistors), which can be implemented on one or more ICs.

By implementing the input buffer circuit 708 as one of the example circuits 100, 200 described herein, the input signal provided by the controller 702 can be propagated to the amplifier circuit 710 and the output stage with reduced propagation delay compared to many existing approaches. Additionally, or alternatively, the signals at 720 and 722 can be provided with reduced signal distortion and increased accuracy over a wide range of inputs compared to many existing approaches.

In this description, numerical designations “first”, “second”, etc. are not necessarily consistent with same designations in the claims herein. Additionally, the term “couple” may cover connections, communications, or signal paths that enable a functional relationship consistent with this description. For example, if device A generates a signal to control device B to perform an action, then: (a) in a first example, device A is directly coupled to device B; or (b) in a second example, device A is indirectly coupled to device B through intervening component C if intervening component C does not alter the functional relationship between device A and device B, so device B is controlled by device A via the control signal generated by device A.

Also, in this description, a device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof. Furthermore, a circuit or device described herein as including certain components may instead be configured to couple to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor wafer and/or integrated circuit (IC) package) and may be configured to couple to at least some of the passive elements and/or the sources to form the described structure, either at a time of manufacture or after a time of manufacture, such as by an end user and/or a third party.

Modifications are possible in the described embodiments, and other embodiments are possible, within the scope of the claims.

What is claimed is:

1. A circuit comprising:
an input divider network having a first divider input, a second divider input, a first threshold input, a second threshold input, a first divider output, and a second divider output, in which the second divider input is coupled to a signal ground terminal;
a threshold generator having first and second threshold outputs and a selection input, in which the first threshold output is coupled to the first threshold input and the second threshold output is coupled to the second threshold input; and
a comparator having first and second comparator inputs and a comparator output, in which the first comparator input is coupled to first divider output, the second comparator input is coupled to the second divider output, and the comparator output is coupled to the selection input.

2. The circuit of claim 1, wherein the input divider network comprises:
a resistive network comprising:
a first resistor divider having a first resistor coupled between the first comparator input and the first divider input and a second resistor coupled between the first comparator input and the first threshold input; and
a second resistor divider having a third resistor coupled between the second comparator input and the second divider input and a fourth resistor coupled between the second comparator input and the second threshold input;
a capacitive network comprising:
a first capacitor divider including first and second capacitors, in which the first capacitor is coupled between the first divider input and the first divider output, the second capacitor is coupled between the first divider output and a driver ground terminal, in which a parasitic component is coupled between the driver ground terminal and the signal ground terminal; and
a second capacitor divider including third and fourth capacitors, in which the third capacitor is coupled between the second divider input and the second divider output, and a fourth capacitor is coupled between the second divider output and the driver ground terminal.

3. The circuit of claim 2, wherein the first and second divider inputs define a differential input, the resistive network is configured to provide a stepped-down version of a differential input signal at the differential input, and the capacitive network is configured propagate the stepped-down version of the differential input signal to the first and second comparator inputs.

4. The circuit of claim 2, comprising a packaged semiconductor die having first and second input terminals, and the driver ground terminal, wherein the packaged semiconductor die comprises the resistive network, the capacitive network, the threshold generator, and the comparator, the first divider input is coupled to the first input terminal, the second divider input is coupled to the second input terminal, and the second input terminal is coupled to the signal ground terminal.

5. The circuit of claim 1, wherein the threshold generator comprises:
a multiplexer having first and second multiplexer inputs, the selection input, and a multiplexer output, in which the multiplexer output is coupled to the first threshold input;
a first buffer having a first buffer input and a first buffer output, in which the first buffer output is coupled to the first multiplexer input;
a second buffer having a second buffer input and a second buffer output, in which the second buffer output is coupled to the second multiplexer input; and
a third buffer having a third buffer input and a third buffer output, in which the third buffer output is coupled to the first threshold input.

6. The circuit of claim 5, wherein the threshold generator further comprises:
a voltage buffer having a first voltage input and a voltage output; and
a ladder circuit having a second voltage input, a first ladder output, a second ladder output and a third ladder output, in which the second voltage input is coupled to the voltage output, the first ladder output is coupled to the first buffer input, the second ladder output is coupled to the second buffer input, and the third ladder output is coupled to the third buffer input.

7. The circuit of claim 5, wherein the threshold generator further comprises:
a first capacitor coupled between the first buffer output and the third buffer output; and
a second capacitor coupled between the second buffer output and the third buffer output.

8. The circuit of claim 1, further comprising a capacitor coupled between the second comparator input and the comparator output.

9. The circuit of claim 1, further comprising a controller having a signal output coupled to the first divider input, in which the controller is configured to provide a pulse-width modulated signal at the signal output.

10. The circuit of claim 9, further comprising a first integrated circuit and a second integrated circuit, wherein the first integrated circuit includes the controller, and the second integrated circuit includes the input divider network and the comparator, and the signal output is directly coupled to the first divider input.

11. A circuit, comprising:
an input divider network configured to provide a stepped-down differential input signal, based on an input signal, a ground signal, a first threshold voltage, and a second threshold voltage, in which the input signal and the ground signal define a differential input signal;
a threshold generator configured to provide a provide the first threshold voltage and the second threshold voltage, in which the second threshold voltage changes responsive to a comparator output signal and the first threshold voltage is substantially constant; and
a comparator configured to provide the comparator output signal based on the stepped-down differential input signal.

12. The circuit of claim 11, wherein the input divider network comprises:
a resistor divider including an arrangement of resistors configured to step down a common mode portion of the input signal and provide a stepped down version of the input signal; and
a capacitor divider including an arrangement of capacitors configured to provide the stepped down differential input signal to the comparator.

13. The circuit of claim 12, further comprising a semiconductor die that includes the comparator, the threshold generator, the resistor divider, and the capacitor divider.

14. The circuit of claim 13, further comprising a controller configured to provide the input signal at a controller output, in which the input signal is a modulated signal.

15. The circuit of claim 14, wherein the semiconductor die includes an input terminal coupled to an input of the input divider network, the controller output is directly coupled to the input terminal of the semiconductor die.

16. The circuit of claim 11, wherein the threshold generator is configured to provide the first threshold voltage at a first threshold output and the second threshold voltage at a second threshold output, in which the second threshold voltage changes between a first reference voltage and a second reference voltage responsive to the comparator output signal.

17. The circuit of claim 16, wherein the threshold generator comprises:
a voltage supply circuit configured to provide the first reference voltage at a first voltage output, the second reference voltage at a second voltage output, and the first threshold voltage at the first threshold output; and
a multiplexer configured to provide one of the first reference voltage and the second reference voltage to the second threshold output responsive to the comparator output signal.

18. The circuit of claim 17, wherein the threshold generator further comprises:
a first capacitor coupled between the first voltage output and the first threshold output; and
a second capacitor coupled between the second voltage output and the first threshold output.

19. A system, comprising:
a controller having a signal output terminal and a signal ground terminal;
a driver circuit having a first input signal terminal, a second input signal terminal, a driver ground terminal, and a driver output terminal, the driver circuit comprising:
an input buffer circuit, comprising:
an input divider network having first and second differential inputs, first and second threshold inputs, and first and second differential outputs, in which the first differential input is coupled to the signal output terminal and the second differential input is coupled to the signal ground terminal;
a threshold generator having first and second threshold outputs and a selection input, in which the first threshold output is coupled to the first threshold input, and the second threshold output is coupled to the second threshold input; and
a comparator having first and second comparator inputs and a comparator output, in which the first comparator input is coupled to the first differential output, the second comparator input is coupled to the second differential output, and the comparator output is coupled to the selection input; and
an amplifier circuit having an amplifier input and an amplifier output, in which the amplifier input is coupled to the comparator output and the amplifier output is coupled to the driver output terminal.

20. The system of claim 19, further comprising an output stage having a drive input, a switching output and an output ground terminal, in which the drive input is coupled to the driver output terminal, the output ground terminal is coupled to the driver ground terminal, and the output ground terminal is coupled to the signal ground terminal through a parasitic inductance.
